(19) United States
(12) Patent Application Publication
(10) Pub. No.: US 2025/0107151 A1
(43) Pub. Date: Mar. 27, 2025

(54) Thin Film Transistor Substrate and Display Device Using the Same

(71) Applicant: LG Display Co., Ltd., Seoul (KR)

(72) Inventors: Ahrum Sohn, Paju-si (KR); JaeYoung Oh, Paju-si (KR)

(21) Appl. No.: 18/822,885

(22) Filed: Sep. 3, 2024

(30) Foreign Application Priority Data
Sep. 26, 2023 (KR) 10-2023-0129520

(51) Int. Cl. H01L 29/786; H01L 29/417

(52) U.S. Cl. CPC H10D 30/6734; H10D 30/6729; H10D 30/6757

(57) ABSTRACT

A thin film transistor substrate presented herein includes a substrate, a first gate electrode on the substrate, the first gate electrode including a first portion and a second portion, an active layer on the first gate electrode, a second gate electrode on the active layer, the second gate electrode overlapping at least the first portion of the first gate electrode, a source electrode connected to a first side of the active layer, and a drain electrode connected to a second side of the active layer, wherein the first portion overlaps the second gate electrode, the second portion protrudes from an end of the first portion in a direction towards the source electrode or the drain electrode, and a thickness of the second portion is smaller than a thickness of the first portion. A display device includes the thin film transistor substrate as presented herein.

### CROSS-REFERENCE TO RELATED APPLICATION

This application claims the priority from the Republic of Korea Patent Application No. 10-2023-0129520 filed on Sep. 26, 2023, which is hereby incorporated by reference in its entirety.

### BACKGROUND

### Field

The present disclosure relates to a thin film transistor substrate and a display device using the same.

### Description of Related Art

Since thin film transistors can be manufactured on glass or plastic substrates, they are widely used as switching or driving elements of display devices such as liquid crystal display devices or organic light emitting devices.

According to the positional relationship between the gate electrode and the active layer, the thin film transistor can be divided into a top gate structure in which the gate electrode is provided on the active layer, a bottom gate structure in which the gate electrode is provided under the active layer, and a double gate structure in which two or more gate electrodes are provided above and below the active layer.

Among them, the thin film transistor having a double gate structure may be formed such that the length of the gate electrode provided at the lower portion is longer than the length of the gate electrode provided at the upper portion. In this case, effects of the upper gate electrode and the lower gate electrode having different lengths on the active layer are different from each other, and thus junction stress may be formed high in the active layer. A region in which junction stress is formed high in the active layer may be defined as a so-called high junction stress region (HJS region). When such an HJS region occurs, there is a problem that the threshold voltage Vth may significantly change during the process of driving the thin film transistor (turn-on), and the life of the device may decrease as the threshold voltage Vth changes. Therefore, it is important to minimize or at least reduce such HSJ region.

### SUMMARY

The present disclosure has been made in view of the above problems, and it is an object of the present disclosure to provide a thin film transistor substrate that minimizes or at least reduces the HSJ area by adjusting the intensity of the electric field of the upper gate electrode and the lower gate electrode on the active layer in a region where the upper gate electrode and the lower gate electrode do not overlap, and a display device including the same.

In accordance with one or more embodiments of the present disclosure, the above and other objects can be accomplished by the provision of a thin film transistor substrate comprising a substrate, a first gate electrode on the substrate, the first gate electrode including a first portion and a second portion, an active layer on the first gate electrode, a second gate electrode on the active layer, the second gate electrode overlapping at least the first portion of the first gate electrode, a source electrode connected to a first side of the active layer, and a drain electrode connected to a second side of the active layer, wherein the second portion protrudes from an end of the first portion in a first direction towards the source electrode or the drain electrode, and a thickness of the second portion is smaller than a thickness of the first portion, and a display device including the same.

Furthermore, the above and other objects can be accomplished by the provision of a thin film transistor substrate comprising a substrate, a first gate electrode on the substrate, the first gate electrode including a first portion and a plurality of second portions, the plurality of second portions spaced apart from each other with a plurality of first grooves interposed between the plurality of second portions, an active layer on the first gate electrode, a second gate electrode on the active layer, the second gate electrode overlapping at least a portion of the first gate electrode, a source electrode connected to a first side of the active layer, and a drain electrode connected to a second side of the active layer, wherein the plurality of second portions protrude from an end of the first portion in a first direction towards the source electrode or the drain electrode, and wherein an end of the second gate electrode overlaps a region from a first end of the first portion to an end of a second portion of the plurality of second portions that is connected to a second end of the first portion, and a display device including the same.

Furthermore, the above and other objects can be accomplished by the provision of a thin film transistor substrate comprising a first gate electrode extending in a first direction, the first gate electrode including a first portion and a plurality of second portions that protrude from a first end of the first portion along a second direction that is different than the first direction, the plurality of second portions spaced apart from each other, an active layer on the first gate electrode and extending in the second direction, the active layer partially overlapping the first portion and a subset of the plurality of second portions along the first direction, a source electrode connected to a first side of the active layer, a drain electrode connected to a second side of the active layer, the second side of the active layer opposite to the first side of the active layer along the second direction, and a second gate electrode on the active layer and extending in the first direction, the second gate electrode partially overlapping the first gate electrode along the second direction without overlapping ends of the plurality of second portions.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1A is a plan view of a thin film transistor substrate according to an embodiment of the present disclosure.

FIG. 1B is a plan view of a first gate electrode and a second gate electrode of a thin film transistor substrate according to an embodiment of the present disclosure.

FIG. 2A is a cross-sectional view of a thin film transistor substrate according to an embodiment of the present disclosure. In this case, the cross-sectional view in FIG. 2A corresponds to the cross-section taken along the line I-I′ in FIG. 1A.

FIG. 2B is a cross-sectional view of a thin film transistor substrate according to an embodiment of the present disclosure. In this case, the cross-sectional view in FIG. 2B corresponds to the cross-section along the line II-II′ in FIG. 1A.

FIG. 2C is a cross-sectional view of a thin film transistor substrate according to an embodiment of the present disclosure. In this case, the cross-sectional view in FIG. 2C corresponds to the cross-section taken along the line III-III′ in FIG. 1A.

FIG. 3A is a cross-sectional view of a thin film transistor substrate according to another embodiment of the present disclosure. In this case, the cross-sectional view in FIG. 3A corresponds to the cross-section taken along the line I-I′ in FIG. 1A.

FIG. 3B is a cross-sectional view of a thin film transistor substrate according to another embodiment of the present disclosure. In this case, the cross-sectional view in FIG. 3B corresponds to the cross-section taken along the line II-II′ in FIG. 1A.

FIG. 4 is a plan view of a thin film transistor substrate according to another embodiment of the present disclosure.

FIG. 5A is a cross-sectional view of a thin film transistor substrate according to another embodiment of the present disclosure. In this case, the cross-sectional view in FIG. 5A corresponds to the cross-section taken along the line of V-V′ in FIG. 4.

FIG. 5B is a cross-sectional view of a thin film transistor substrate according to another embodiment of the present disclosure. In this case, the cross-sectional view in FIG. 5B corresponds to the cross-section taken along the line VI-VI′ in FIG. 4.

FIG. 6 is a plan view of a thin film transistor substrate according to another embodiment of the present disclosure.

FIG. 7A is a cross-sectional view of a thin film transistor substrate according to another embodiment of the present disclosure. In this case, the cross-sectional view in FIG. 7A corresponds to the cross-section taken along the line VII-VII′ in FIG. 6.

FIG. 7B is a cross-sectional view of a thin film transistor substrate according to another embodiment of the present disclosure. In this case, the cross-sectional view in FIG. 7B corresponds to the cross-section taken along the line VIII-VIII′ in FIG. 6.

FIG. 8 is a plan view of a thin film transistor substrate according to another embodiment of the present disclosure.

FIG. 9 is a plan view of a thin film transistor substrate according to another embodiment of the present disclosure.

FIG. 10 is a cross-sectional view of a display device including a thin film transistor substrate according to an embodiment of the present disclosure.

FIG. 11 is a schematic view of a display device according to an embodiment of the present disclosure.

FIG. 12 is a circuit diagram of a pixel included in a display device according to an embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically. The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

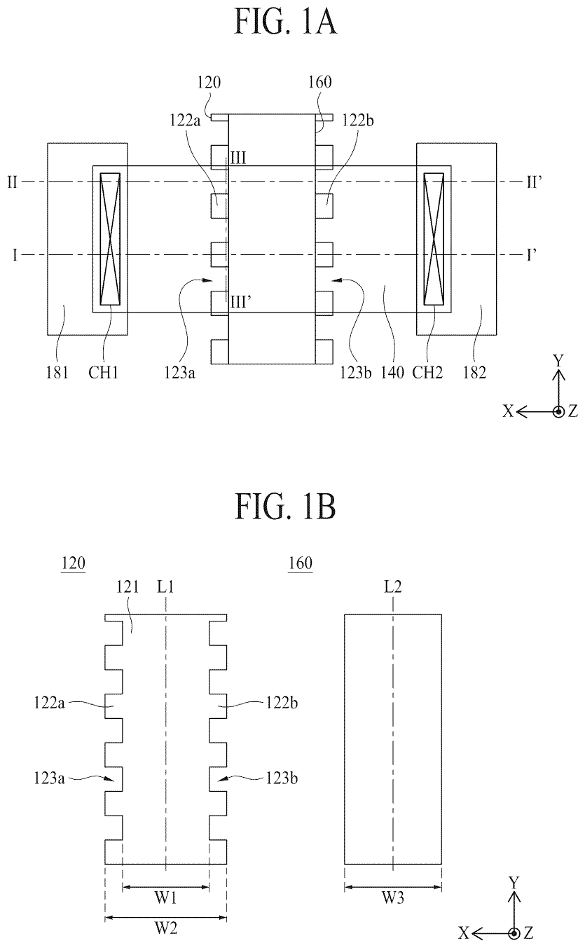

FIG. 1A is a plan view of a thin film transistor substrate according to an embodiment of the present disclosure. And FIG. 1B is a plan view of a first gate electrode and a second gate electrode of a thin film transistor substrate according to an embodiment of the present disclosure.

First, as shown in FIG. 1A, a thin film transistor substrate according to an embodiment of the present disclosure may include a first gate electrode 120, an active layer 140, a second gate electrode 160, a source electrode 181, and a drain electrode 182.

The active layer 140 may extend in a first direction X, for example, a horizontal direction. In this case, the first direction X may be defined as a direction facing the source electrode 181 and the drain electrode 182.

A first contact hole CH1 may be provided on one side of the active layer 140, for example, a left side, and a second contact hole CH2 may be provided on another side of the active layer 140, for example, a right side. In this case, one side of the active layer 140 may be electrically connected to the source electrode 181 through the first contact hole CH1, and another side of the active layer 140 may be electrically connected to the drain electrode 182 through the second contact hole CH2.

Each of the first gate electrode 120 and the second gate electrode 160 may extend in a second direction Y, for example, a vertical direction. In this case, the second direction Y may be defined as a direction orthogonal to the first direction X. Alternatively, a vertical direction can be referred to as a first direction Y, and a horizontal direction can be referred to as a second direction X.

Each of the first gate electrode 120 and the second gate electrode 160 may overlap the active layer 140, and each of the first gate electrode 120 and the second gate electrode 160 may overlap at least partially with each other.

The first gate electrode 120 and the second gate electrode 160 may be provided to have different shapes. Different shapes of the first gate electrode 120 and the second gate electrode 160 will be described in more detail with reference to FIG. 1B below.

As shown in FIG. 1B, the first gate electrode 120 may include a first portion 121, a plurality of second portions 122a, and a plurality of third portions 122b. In this case, the first portion 121 is a body portion of the first gate electrode 120, and the plurality of second portions 122a and the plurality of third portions 122b correspond to protrusions protruding from the first portion 121 in the first direction X.

The first portion 121 may extend in the second direction Y and may have a first width W1 in the first direction X. The first width W1 may be defined as the minimum distance from one end of the first portion 121, for example, the left end to another end of the first portion 121, for example, the right end.

The plurality of second portions 122a and the plurality of third portions 122b may be provided on one side and another side of the first portion 121, respectively. For example, the plurality of second portions 122a may protrude from one side of the first portion 121, for example a left side in the first direction X and extend in the direction of the source electrode 181, and the plurality of third portions 122b may protrude in the first direction X from another side of the first portion 121, for example, the right side, and extend in the direction of the drain electrode 182.

A length in the first direction X and a length in the second direction Y of each of the plurality of second portions 122a may be the same, but are not limited thereto. For example, a partial second portion 122a overlapping the active layer 140 among the plurality of second portions 122a may be formed to have the same length in the first direction X and the second direction Y, and another portion of the plurality of second portions 122a that does not overlap the active layer 140 may be formed to have a length different from that of the partial second portion 122a in the first direction X and the second direction Y.

Likewise, a length in the first direction X and a length in the second direction Y of each of the plurality of third portions 122b may be the same. However, the present disclosure is not limited thereto.

The plurality of second portions 122a and the plurality of third portions 122b may be provided symmetrically with respect to the first central line L1, which is a virtual line passing through the center of the first portion 121. However, the present disclosure is not limited thereto, and the plurality of second portions 122a and the plurality of third portions 122b may be provided to deviate from each other with respect to the first central line L1.

The first gate electrode 120 may include a plurality of grooves 123a and 123b, and the plurality of grooves 123a and 123b may be provided between the plurality of second portions 122a and the plurality of third portions 122b of the first gate electrode 120. Specifically, the plurality of grooves 123a and 123b may include a plurality of first grooves 123a adjacent to the source electrode 181 and a plurality of second grooves 123b adjacent to the drain electrode 182. The plurality of first grooves 123a may be provided between a plurality of second portions 122a of the first gate electrode 120, and the plurality of second grooves 123b may be provided between a plurality of third portions 122b of the first gate electrode 120.

The length in the first direction X and the length in the second direction Y of each of the plurality of first grooves 123a may be the same, but are not limited thereto. For example, the plurality of first grooves 123a overlapping the active layer 140 are formed to have the same length in the first direction X and the second direction Y, and the plurality of first grooves 123a not overlapping the active layer 140 may be formed to have different lengths in the first direction X and the second direction Y.

Likewise, the length in the first direction X and the length in the second direction Y of each of the plurality of second grooves 123b may be the same, but are not limited thereto.

The first gate electrode 120 may have a second width W2 in the first direction X. The second width W2 may be defined as a minimum distance from one end of the plurality of second portions 122a, for example, a left end to one end of the plurality of third portions 122b, for example, a right end, and the second width W2 may be greater than the first width W1 of the first portion 121.

Unlike the first gate electrode 120, the second gate electrode 160 may not include a plurality of grooves or a plurality of protrusions. In this way, the first gate electrode 120 and the second gate electrode 160 may be provided in different shapes. The second gate electrode 160 may overlap an entirety of the first portion 121 along the first direction X and the second direction Y. The second gate electrode 160 may be non-overlapping with the plurality of second portions 122a.

The second gate electrode 160 may extend in the second direction Y and may have a third width W3 in the first direction X. The third width W3 may be defined as the minimum distance from one end of the second gate electrode 160, for example, a left end to another end of the second gate electrode 160, for example, a right end.

According to an embodiment of the present disclosure, the third width W3 of the second gate electrode 160 may be the same as the first width W1 of the first portion 121 of the first gate electrode 120, and the third width W3 may be smaller than the second width W2 of the first gate electrode 120.

According to an embodiment of the present disclosure, the first gate electrode 120 and the second gate electrode 160 may overlap each other. In this case, the first central line L1 passing through the center of the first gate electrode 120 and the second central line L2 passing through the center of the second gate electrode 160 may overlap each other to coincide with each other on a plane.

Since the third width W3 of the second gate electrode 160 is provided to be smaller than the second width W2 of the first gate electrode 120 and equal to the first width W1 of the first portion 121, the first gate electrode 120 and the second gate electrode 160 are provided so that the first central line L1 of the first gate electrode 120 and the second central line L2 of the second gate electrode 160 coincide with each other in a plane, as shown in FIG. 1A again, one end of the second gate electrode 160, for example, the left end of the second gate electrode 160, may overlap an area provided between one end of the first portion 121, for example, a left end and one end of the second portion 122a, for example, a left end. Likewise, another end of the second gate electrode 160, for example, the right end, may overlap an area provided between another end of the first portion 121, for example, a right end and one end of the third portion 122b, for example, a right end.

Specifically, the one end of the second gate electrode 160 may coincide with the one end of the first portion 121 on a plane view, and another end of the second gate electrode 160 may coincide with another end of the first portion 121 on a plane view.

According to an embodiment of the present disclosure, as the plurality of first grooves 123a and the plurality of second grooves 123b are formed on one side and the other side of the first gate electrode 120, respectively, a region where the first gate electrode 120 and the active layer 140 overlap each other and do not overlap with the second gate electrode 160 may be reduced. By forming a double gate structure in this way, the HSJ region, which is a high stress junction region, may be minimized or at least reduced in a region where the first gate electrode 120 and the active layer 140 overlap each other and do not overlap with the second gate electrode 160.

Conventionally, in the case of a double gate structure, the width of the lower gate electrode is formed to be greater than the width of the upper gate electrode. In this case, the electric field applied to the active layer from the lower gate electrode having a relatively large width and the electric field applied to the active layer from the upper gate electrode having a relatively small width are different from each other, so that electric fields applied to the channel part of the active layer are asymmetrically formed. Note that an asymmetrically formed electric field means that an electric field of a relatively narrow area like an upper gate electrode is applied to the upper area of the upper active layer, and an electric field of a relatively large area like a lower gate electrode is applied to the lower area of the active layer.) Thus, a high stress region (hereinafter referred to as the HJS region) is generated in a region where the channel part of the active layer is formed. In this case, when the HSJ region occurs, the threshold voltage Vth of the thin film transistor changes, and the life of the element is shortened.

According to an embodiment of the present disclosure, as the plurality of first grooves 123a and the plurality of second grooves 123b are formed on one side and another side of the first gate electrode 120, an area of a region where the first gate electrode 120 and the active layer 140 overlap each other and do not overlap the second gate electrode 160 may be reduced. By forming a double gate structure in this way, an electric field generated from the first gate electrode 120 may not be applied to the active layer 140 in the region where the plurality of first grooves 123a and the plurality of second grooves 123b are formed, and thus, the phenomenon in which the electric field applied from the first gate electrode 120 to the active layer 140 and the electric field applied from the second gate electrode 160 to the active layer 140 are asymmetrically formed may be reduced. Therefore, the HJS area is relatively reduced, and thus a problem in which the characteristics of the device are deteriorated or the life of the thin film transistor substrate is reduced due to a change in the threshold voltage Vth of the thin film transistor substrate may be minimized, suppressed or reduced.

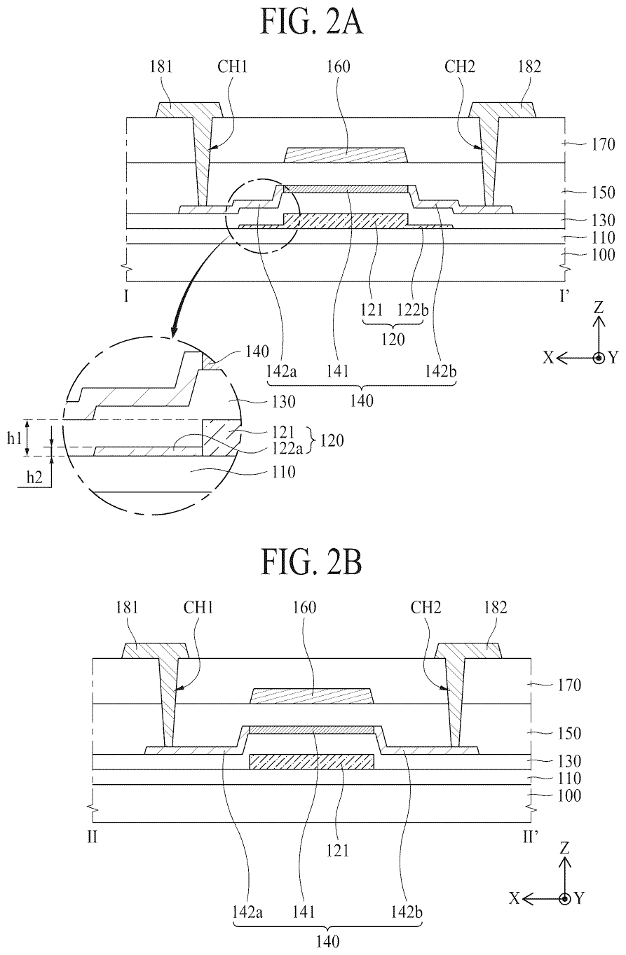

FIG. 2A is a cross-sectional view of a thin film transistor substrate according to an embodiment of the present disclosure. In this case, the cross-sectional view in FIG. 2A corresponds to the cross-section taken along the line I-I′ in FIG. 1A.

As shown in FIG. 2A, a thin film transistor substrate according to an embodiment of the present disclosure may include a substrate 100, a buffer layer 110, a first gate electrode 120, a first gate insulating layer 130, an active layer 140, a second gate insulating layer 150, a second gate electrode 160, an interlayer insulating layer 170, a source electrode 181, and a drain electrode 182.

The substrate 100 may be made of glass or plastic. In particular, the substrate 100 may be made of transparent plastic having flexible characteristics, for example, polyimide. When the polyimide is used as the substrate 100, considering that a high-temperature deposition process is performed on the substrate 100, heat-resistant polyimide capable of withstanding high temperature may be used.

The buffer layer 110 may be formed on the substrate 100. The buffer layer 110 may protect the active layer 140 by blocking air and moisture. The buffer layer 110 may be formed of an inorganic insulating material such as silicon oxide, silicon nitride, or metal oxide, but is not limited thereto and may be formed of an organic insulating material. The buffer layer 110 may be formed of a single layer, a plurality of layers, or may be omitted.

The first gate electrode 120 may be formed on the buffer layer 110. Meanwhile, although not illustrated, the first gate electrode 120 may be formed on the substrate 100 when the buffer layer 110 is omitted.

According to an embodiment of the present disclosure, the first gate electrode 120 may include a first portion 121, a second portion 122a, and a third portion 122b. In this case, the second portion 122a may protrude from one side of the first portion 121, for example, the left side, and extend toward the source electrode 181, and the third portion 122b may protrude from another side of the first portion 121, for example, the right side, and extend toward the drain electrode 182.

The second portion 122a and the third portion 122b may be formed symmetrically with respect to the first portion 121.

According to an embodiment of the present disclosure, as shown in enlarged view in FIG. 2A, the first gate electrode 120 may be formed to be stepped. Specifically, the first portion 121 may have a first height h1 from the buffer layer 110, and the second portion 122a and the third portion 122b may have a second height h2 from the buffer layer 110. In this case, the first height h1 may be greater than the second height h2.

The first gate electrode 120 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The first gate electrode 120 may have a structure including one metal layer or a multilayer structure including at least two metal layers each having different physical properties.

The first gate insulating layer 130 may be provided on the first gate electrode 120. Specifically, the first gate insulating layer 130 may be provided on the entire surface of the substrate 100, and may be provided on the first gate electrode 120 and the buffer layer 110. As a result, the first gate electrode 120 may be surrounded by the buffer layer 110 and the first gate insulating layer 130.

The first gate insulating layer 130 may include a silicon nitride layer SiNx or a silicon oxide layer SiOx, but is not limited thereto. The first gate insulating layer 130 may be formed of a single layer or a plurality of layers including an inorganic insulating material and/or an organic insulating material.

The active layer 140 may be provided on the first gate insulating layer 130.

The active layer 140 may include a semiconductor material, for example, an oxide semiconductor material. The oxide semiconductor material may include at least one of, for example, an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

The active layer 140 may include a channel part 141, a first connection part 142a connected to a first side of the channel part 141, for example, a right side, and a second connection part 142b connected to a second side of the channel part 141 that is opposite the first side of the channel part 141, for example, a left side.

The first connection part 142a and the second connection part 142b may have conductive characteristics by a conducting process of performing ion doping or plasma treatment on a semiconductor material using the second gate electrode 160 as a mask.

The conducting process may be defined as a process of imparting conductive properties to an oxide semiconductor material. The oxide semiconductor material having the conducting process performed may have conductive properties. The conducting process may include, for example, a doping process using dopant ions and a plasma process of applying plasma to conduct the same. Through the conducting process, a partial region of the active layer 140, for example, the first connection part 142a and the second connection part 142b may be conductive to have conductive properties. Accordingly, the first connection part 142a and the second connection part 142b may have better conductivity than the channel part 141, and each of them may serve as a wiring or source/drain electrode.

The channel part 141 may overlap the first portion 121 of the first gate electrode 120, the first connection part 142a may overlap the second portion 122a of the first gate electrode 120, and the second connection part 142b may overlap the third portion 122b of the first gate electrode 120.

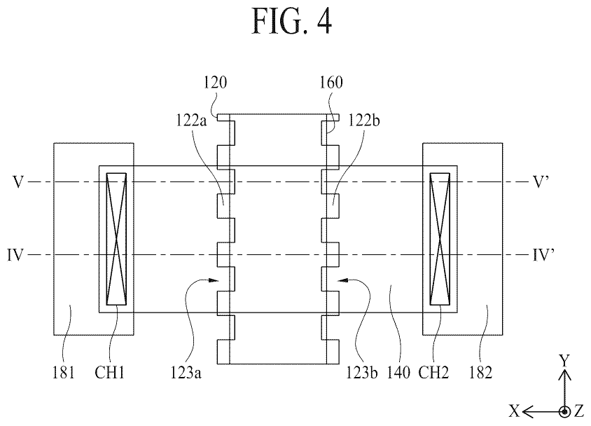

One end of the channel part 141, for example, a left end may coincide with one end of the first portion 121, for example, a left end, and another end of the channel part 141, for example, a right end, may coincide with another end of the first portion 121. However, the present disclosure is not limited thereto, and as illustrated in FIG. 5A to be described later, the channel part 141 may also overlap the first portion 121, the second portion 122a, and the third portion 122b.

The first connection part 142a and the second connection part 142b may overlap the second portion 122a and the third portion 122b, respectively.

According to an embodiment of the present disclosure, the active layer 140 may be provided to be stepped according to steps formed in the first portion 121, the second portion 122a, and the third portion 122b of the first gate electrode 120. Each of the first connection part 142a and the second connection part 142b may have a stepped form.

Therefore, the distance between the active layer 140 and the first portion 121 along a third direction Z and the distance between the active layer 140 and the second portion 122a or the third portion 122b along the third direction Z may be the same. In this case, each distance may be defined as the shortest distance between the active layer 140 and the first gate electrode 120.

The first gate insulating layer 130 may be provided on the active layer 140. Specifically, the first gate insulating layer 130 may be provided on the entire surface of the substrate 100, and may be provided on the active layer 140 and the buffer layer 110. As a result, the active layer 140 may be surrounded by the buffer layer 110 and the first gate insulating layer 130.

The second gate insulating layer 150 may be formed on the active layer 140. Specifically, the second gate insulating layer 150 may be provided on the entire surface of the substrate 100, and may be provided on the active layer 140 and the first gate insulating layer 130. As a result, the active layer 140 may be surrounded by the first gate insulating layer 130 and the second gate insulating layer 150.

The second gate insulating layer 150 may include a silicon nitride layer SiNx or a silicon oxide layer SiOx, but is not limited thereto. The second gate insulating layer 150 may be formed of a single layer or a plurality of layers including an inorganic insulating material and/or an organic insulating material. Meanwhile, although not illustrated, the second gate insulating layer 150 is not limited to being provided on the entire surface of the substrate 100, but may be formed to match one end and another end of the second gate electrode 160. In this case, the active layer 140 may not be formed to be surrounded by the first gate insulating layer 130 and the second gate insulating layer 150.

The second gate electrode 160 may be formed on the second gate insulating layer 150.

One end of the second gate electrode 160 may coincide with one end of the first portion 121 of the first gate electrode 120, for example, a left end, and another end of the second gate electrode 160 may coincide with another end of the first portion 121 of the first gate electrode 120, for example, a right end.

The second gate electrode 160 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The second gate electrode 160 may have a structure including one metal layer or a multilayer structure including at least two metal layers each having different physical properties.

The interlayer insulating layer 170 may insulate the second gate electrode 160 and the source electrode 181 and further insulate the second gate electrode 160 and the drain electrode 182. The interlayer insulating layer 170 may be formed of a single layer or a plurality of layers including an inorganic insulating material and/or an organic insulating material.

A first contact hole CH1 and a second contact hole CH2 may be provided in the interlayer insulating layer 170. Accordingly, a portion of the upper surface of the first connection part 142a of the active layer 140 may be exposed by the first contact hole CH1, and further, a portion of the upper surface of the second connection part 142b of the active layer 140 may be exposed by the second contact hole CH2. The first connection part 142a of the active layer 140 may extend in the first direction X towards the source electrode 181, and the second connection part 142b of the active layer 140 may extend in the first direction X towards the drain electrode 182.

The channel part 141 of the active layer 140 may overlap the first portion 121. The first connection part 142a may overlap a subset of the plurality of second portions 122a. The second connection part 142b may overlap a subset of the plurality of third portions 122b.

The source electrode 181 and the drain electrode 182 may be disposed on the interlayer insulating layer 170.

The source electrode 181 may be electrically connected to the first connection part 142a of the active layer 140 by the first contact hole CH1, and the drain electrode 182 may be electrically connected to the second connection part 142b of the active layer 140 by the second contact hole CH2.

The source electrode 181 and the drain electrode 182 may be formed of the same material as the second gate electrode 160, but are not limited thereto and may be formed of a material according to knowledge of the art.

FIG. 2B is a cross-sectional view of a thin film transistor substrate according to an embodiment of the present disclosure. In this case, the cross-sectional view in FIG. 2B corresponds to the cross-section along the line II-II′ in FIG. 1A. Meanwhile, the embodiment in FIG. 2B is the same as the embodiment in FIG. 2A except for the configuration of the first gate electrode, and thus different configurations will be mainly described below.

As shown in FIG. 2B, the first gate electrode 120 may include only the first portion 121 without the second portion and the third portion (see 122a and 122b in FIG. 2A). Referring to FIG. 1A, a plurality of first grooves and a plurality of second grooves (see 123a and 123b in FIG. 1A) are formed on one side and another side of the first portion 121, and thus only the first portion 121 may be formed on the buffer layer 110 without a separate second portion and a third portion (see 122a and 122b in FIG. 2A).

According to an embodiment of the present disclosure, since the first gate electrode 120 includes only the first portion 121, an electric field applied from the first gate electrode 120 to the active layer 140 and an electric field applied from the second gate electrode 160 to the active layer 140 may be formed symmetrically. Accordingly, the HJS region may not occur or may be minimized or at least reduced, and thus, the degree of change in the threshold voltage Vth of the thin film transistor substrate according to the embodiment may be reduced, and the problem of shortening the life of the element may be solved or at least mitigated.

FIG. 2C is a cross-sectional view of a thin film transistor substrate according to an embodiment of the present disclosure. In this case, the cross-sectional view in FIG. 2C corresponds to the cross-section taken along the line III-III′ in FIG. 1A. Meanwhile, according to an embodiment in FIG. 2C, configurations of the substrate, the buffer layer, the first gate insulating layer, the second gate insulating layer, the interlayer insulating layer, the source electrode, and the drain electrode are the same as those described in the embodiment in FIG. 2A, and thus different configurations will be mainly described below.

As shown in FIG. 2C, the plurality of second portions 122a may be disposed on the buffer layer 110 to be spaced apart from each other by a predetermined interval. A plurality of first grooves 123a are provided between the plurality of second portions 122a. Each two adjacent second portions of the plurality of second portions 122a may be spaced apart by a respective groove of the plurality of first grooves 123a. As described above, the active layer 140 and the first gate electrode 120 may not overlap in the region where the plurality of first grooves 123a are formed.

According to an embodiment of the present disclosure, since the first gate electrode 120 and the active layer 140 do not overlap each other in the region where the plurality of first grooves 123a are formed, the degree to which the electric field is applied to the active layer 140 from the first gate electrode 120 is minimized or at least reduced in the region where the first gate electrode 120 and the active layer 140 overlap each other (see FIG. 1A), and thus the HJS region of the thin film transistor substrate according to the embodiment of the present disclosure may be minimized or at least reduced. Accordingly, a phenomenon in which the threshold voltage Vth of the thin film transistor substrate according to an embodiment of the present disclosure fluctuates and the life of the device is shortened may be suppressed, prevented or reduced.

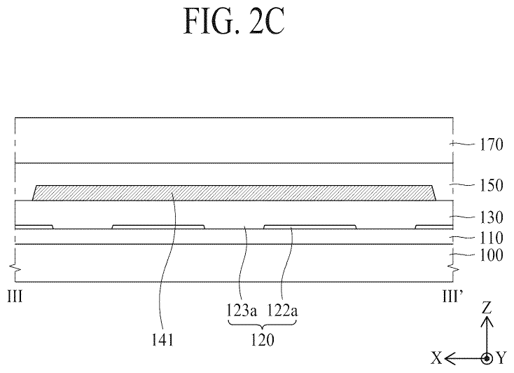

FIG. 3A is a cross-sectional view of a thin film transistor substrate according to another embodiment of the present disclosure. In this case, the cross-sectional view in FIG. 3A corresponds to the cross-section taken along the line I-I′ in FIG. 1A. Meanwhile, the embodiment in FIG. 3A is the same as the embodiment in FIG. 2A except for the configuration of the first gate insulating layer and the active layer, and thus different configurations will be mainly described below.

As shown in FIG. 3A, the first gate insulating layer 130 may be formed not to have the same thickness (or height) but to have different thicknesses. Specifically, as shown in the enlarged view in FIG. 3A, a portion of the first gate insulating layer 130 overlapping the first portion 121 of the first gate electrode 120 may have a third height h3, and another portion of the first gate insulating layer 130 overlapping the second portion 122a of the first gate electrode 120 may have a fourth height h4. In this case, the difference between the fourth height h4 and the third height h3 may be the same as the difference between the first height h1 of the first portion (121 in FIG. 2A) and the second height h2 of the second portion 122a. Meanwhile, the relationship between the first gate insulating layer 130 and the third portion 122b is the same as the relationship between the first gate insulating layer 130 and the second portion 122a, and repeated descriptions thereof will be omitted. A thickness (or height) is defined along a third direction Z that is orthogonal to the vertical direction and the horizontal direction.

According to another embodiment of the present disclosure, the upper surface of the first gate insulating layer 130 may be planarized by forming different heights of a portion of the first gate insulating layer 130 overlapping the first portion 121 and another portion overlapping the second portion 122a or the third portion 122b.

The active layer 140 may be provided on the first gate insulating layer 130. In this case, since the upper surface of the first gate insulating layer 130 is planarized, the active layer 140 may be provided on the first gate insulating layer 130 without a separate step difference.

According to another embodiment of the present disclosure, since the active layer 140 is provided without a separate step difference, a distance between the active layer 140 and the first portion 121 of the first gate electrode 120 along the third direction Z and a distance between the active layer 140 and the second portion 122a or the third portion 122b of the first gate electrode 120 along the third direction Z may be different from each other.

More specifically, as shown in the enlarged view in FIG. 3A, the distance between the active layer 140 and the first portion 121 of the first gate electrode 120 may be the third height h3, and the distance between the active layer 140 and the second portion 122a or the third portion 122b of the first gate electrode 120 may be the fourth height h4. As a result, the distance between the second portion 122a or the third portion 122b and the active layer 140 is increased, and thus the intensity of the electric field applied to the active layer 140 from the second portion 122a or the third portion 122b may be relatively reduced.

As a result, as the intensity of the electric field applied to the active layer 140 from the second portion 122a or the third portion 122b decreases, a problem in which the electric field applied from the first gate electrode 120 and the second gate electrode 160 to the active layer 140 is asymmetrically formed may be eliminated, minimized or reduced. Accordingly, since the HJS region is reduced, the degree to which the threshold voltage Vth of the thin film transistor substrate according to another embodiment of the present disclosure fluctuates may be reduced, and further, a problem in which the life of the thin film transistor substrate according to another embodiment of the present disclosure is shortened may be eliminated, minimized or reduced.

FIG. 3B is a cross-sectional view of a thin film transistor substrate according to another embodiment of the present disclosure. In this case, the cross-sectional view in FIG. 3B corresponds to the cross-section taken along the line II-II′ in FIG. 1A. Meanwhile, the embodiment in FIG. 3B is the same as the embodiment in FIG. 2B except for the configuration of the first gate insulating layer and the active layer, and thus different configurations will be mainly described below.

As shown in FIG. 3B, the first gate insulating layer 130 may not be formed to have the same thickness (or height) but may be formed to have different thicknesses. Therefore, a thickness of a portion of the first gate insulating layer 130 overlapping the first portion 121 and a thickness of another portion of the first gate insulating layer 130 not overlapping the first portion 121 may be different from each other, and in this case, a thickness of a portion of the first gate insulating layer 130 overlapping the first portion 121 may be relatively smaller than a thickness of another portion of the first gate insulating layer 130 not overlapping the first portion 121.

According to another embodiment of the present disclosure, the upper surface of the first gate insulating layer 130 may be planarized by forming different heights of a portion of the first gate insulating layer 130 overlapping the first portion 121 and another portion not overlapping the first portion 121.

The active layer 140 may be provided on the first gate insulating layer 130. In this case, since the upper surface of the first gate insulating layer 130 is planarized, the active layer 140 may be provided on the first gate insulating layer 130 without a separate step difference.

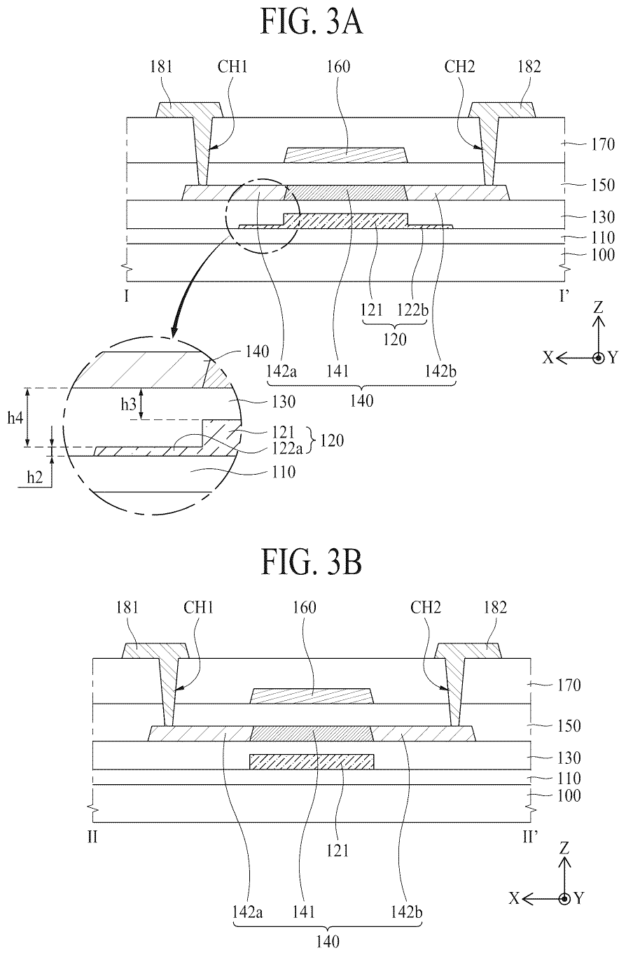

FIG. 4 is a plan view of a thin film transistor substrate according to another embodiment of the present disclosure. Meanwhile, the embodiment in FIG. 4 is the same as the embodiment in FIG. 1A except for the configurations of the first gate electrode and the second gate electrode, and thus different configurations will be mainly described below.

As shown in FIG. 4, the first gate electrode 120 and the second gate electrode 160 may overlap each other. In this case, the first width (see W1 in FIG. 1B) of the first portion of the first gate electrode 120 may be smaller than the third width (see W3 in FIG. 1B) of the second gate electrode 160.

By forming a double gate structure in this way, a plurality of second portions 122a and a plurality of third portions 122b of the first gate electrode 120 may overlap the second gate electrode 160. Furthermore, by overlapping the plurality of second portions 122a and the plurality of third portions 122b with the second gate electrode 160, a plurality of first grooves 123a and a plurality of second grooves 123b may also overlap the second gate electrode 160.

Specifically, one end of the second gate electrode 160, for example, the left end may overlap a region from one end of the first portion 121, for example, to one end of the plurality of second portions 122a, and similarly, another end of the second gate electrode 160, for example, the right end may overlap a region from another end of the first portion 121, for example, the right end to one end of the plurality of third portions 122b.

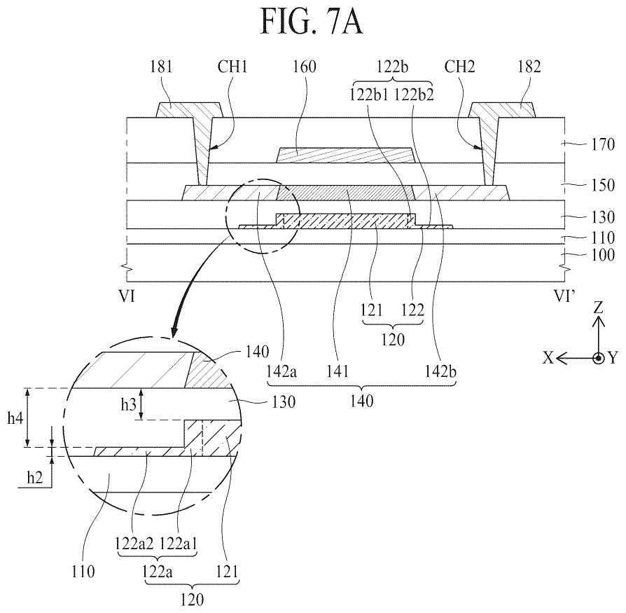

According to another embodiment of the present disclosure, since the second gate electrode 160 overlaps the plurality of second portions 122a, the plurality of third portions 122b, the plurality of first grooves 123a, and the plurality of second grooves 123b, the HJS region may be reduced. At the same time, the HJS region may be reduced even if the first central line (see L1 in FIG. 1B) of the first gate electrode 120 and the second central line (see L2 in FIG. 1B) of the second gate electrode 160 do not match each other on a plane due to a process error in manufacturing a thin film transistor substrate according to another embodiment of the present disclosure. Meanwhile, in this regard, more details will be described with reference to FIG. 8.

FIG. 5A is a cross-sectional view of a thin film transistor substrate according to another embodiment of the present disclosure. In this case, the cross-sectional view in FIG. 5A corresponds to the cross-section taken along the line of V-V′ in FIG. 4. Meanwhile, the embodiment in FIG. 5A is the same as the embodiment in FIG. 3A except for the configuration of the first gate electrode, and thus different configurations will be mainly described below.

As shown in FIG. 5A, the first gate electrode 120 may include a first portion 121, a second portion 122a, and a third portion 122b.

A length of the first portion 121 in the first direction X may be smaller than a length of the second gate electrode 160 in the first direction X. Accordingly, one end of the first portion 121, for example, a left end, may be provided to be relatively closer to a center of the first gate electrode 120 than one end of the second gate electrode 160, for example, a left end.

The second portion 122a may overlap the channel part 141 and the first connection part 142a, and the third portion 122b may overlap the channel part 141 and the second connection part 142b.

The channel part 141 of the active layer 140 may overlap the first portion 121, the second portion 122a, and the third portion 122b. Specifically, one end of the channel part 141 may be provided in a region extending from a boundary between the first portion 121 and the second portion 122a to one end of the second portion 122a, for example the left end. And another end of the channel part 141 may be provided in a region extending from a boundary between the first portion 121 and the third portion 122b to one end of the third portion 122b, for example, the right end.

By forming in this way, one end of the channel part 141 may overlap the second portion 122a, and another end of the channel part 141 may overlap the third portion 122b.

The second gate electrode 160 may overlap the first gate electrode 120. Specifically, the second gate electrode 160 may overlap the first portion 121, the second portion 122a, and the third portion 122b.

One end of the second gate electrode 160, for example, the left end may be provided in a region extending from a boundary between the first portion 121 and the second portion 122a to one end of the second portion 122a, for example, the left end. And another end of the second electrode 160, for example, the right end may be provided in a region extending from a boundary between the first portion 121 and the third portion 122b to one end of the third portion 122b, for example, the right end.

By forming in this way, one end of the second gate electrode 160 may overlap the second portion 122a, and another end of the second gate electrode 160 may overlap the third portion 122b.

According to another embodiment of the present disclosure, one end of the second gate electrode 160 overlaps the second portion 122a, and another end of the second gate electrode 160 overlaps the third portion 122b, thereby maintaining the effect of reducing the HJS region even if the first central line (see L1 in FIG. 1B) of the first gate electrode 120 and the second central line (see L2 in FIG. 1B) of the second gate electrode 160 are misaligned relative to each other in a plan view. Meanwhile, this will be described in more detail with reference to FIG. 8.

FIG. 5B is a cross-sectional view of a thin film transistor substrate according to another embodiment of the present disclosure. In this case, the cross-sectional view in FIG. 5B corresponds to the cross-section taken along the line VI-VI′ in FIG. 4. Meanwhile, the embodiment in FIG. 5B is the same as the embodiment in FIG. 3B except for the configuration of the first portion of the first gate electrode, and thus different configurations will be mainly described below.

As shown in FIG. 5B, the first portion 121 of the first gate electrode 120 may overlap the channel part 141 of the active layer 140 and the second gate electrode 160 and may be formed to have a length shorter than the length of the channel part 141 and the second gate electrode 160 in the first direction X.

One end and another end of the first portion 121 may not correspond to one end and another end of the channel part 141, respectively, and may not correspond to one end and another end of the second gate electrode 160.

Meanwhile, referring to FIGS. 5B and 4, the channel part 141 of the active layer 140 may overlap at least a portion of the plurality of second portions 122a and at least a portion of the plurality of first grooves 123a, and similarly, the channel part 141 of the active layer 140 may overlap at least a portion of the plurality of third portions 122b and at least a portion of the plurality of second grooves 123b.

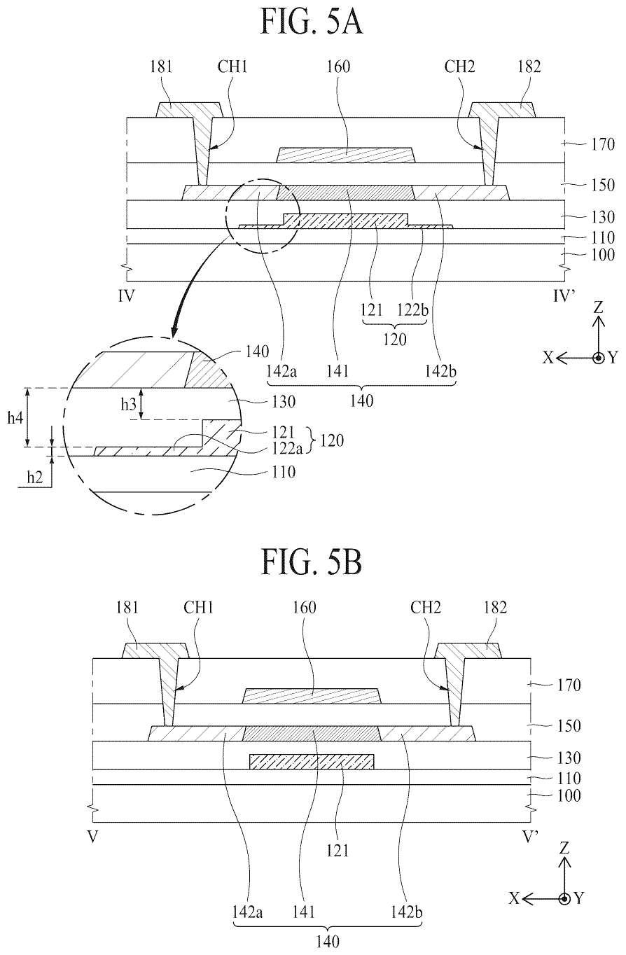

FIG. 6 is a plan view of a thin film transistor substrate according to another embodiment of the present disclosure. Meanwhile, the embodiment in FIG. 6 is the same as the embodiment in FIG. 4 except for the configuration of the first gate electrode, and thus different configurations will be mainly described below.

As shown in FIG. 6, a plurality of second portions 122a of the first gate electrode 120 may include a first region 122al and a second region 122a2, and a plurality of third portions 122b of the first gate electrode 120 include a third region 122b1 and a fourth region 122b2.

The first region 122al may be defined as a portion protruding in the first direction X while contacting one end of the first portion 121, for example, a left end, and the second region 122a2 may be defined as a portion protruding from one end of the first region 122a1 in the first direction X and extending to the source electrode 181.

Similarly, the third region 122b1 may be defined as a portion protruding in the first direction X while contacting another end of the first portion 121, for example, the right end, and the fourth region 122b2 may be defined as a portion protruding from one end of the third region 122b1 in the first direction X and extending to the drain electrode 182.

According to another embodiment of the present disclosure, the first region 122a1 and the third region 122b1 may overlap the second gate electrode 160, and the second region 122a2 and the fourth region 122b2 may not overlap the second gate electrode 160.

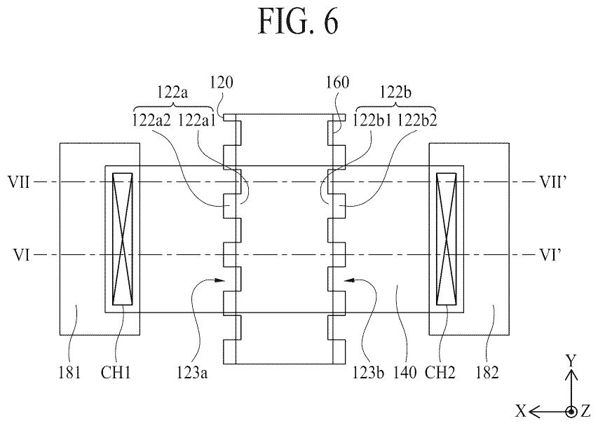

Meanwhile, the heights of the first region 122al and the third region 122b1 and the heights of the second region 122a2 and the fourth region 122b2 may be different from each other, and this will be described in more detail with reference to FIG. 7A.

FIG. 7A is a cross-sectional view of a thin film transistor substrate according to another embodiment of the present disclosure. In this case, the cross-sectional view in FIG. 7A corresponds to the cross-section VII-VII′ in FIG. 6. Meanwhile, the embodiment in FIG. 7A is the same as the embodiment in FIG. 5A except for the configuration of the second portion and the third portion of the first gate electrode, and thus different configurations will be mainly described below.

As shown in FIG. 7A, the second portion 122a and the third portion 122b of the first gate electrode 120 may include different regions having different heights, respectively.

Specifically, the second portion 122a may include a first region 122al that is provided on one side of the first portion 121, for example, on the left side, and a second region 122a2 that is provided on one side of the first region 122a1, for example, on the left side. Furthermore, the first region 122al has the same first height as the height of the first portion 121 (see h1 in FIG. 2A), and the second region 122a2 may have a second height h2 that is different from the first height h1 of the first region 122al. In this case, the first height h1 of the first region 122al may be greater than the second height h2 of the second region 122a2.

Likewise, the third portion 122b may include a third region 122b1 that is provided on another side of the first portion 121, for example, the right side, and a fourth region 122b2 that is provided on one side of the third region 122b1, for example, the right side. Furthermore, the third region 122b1 has the same first height as the height of the first portion 121 (see h1 in FIG. 2A), and the fourth region 122b2 may have a second height h2 that is different from the first height h1 of the third region 122b1. In this case, the first height h1 of the third region 122b1 may be greater than the second height h2 of the fourth region 122b2.

The first region 122al and the third region 122b1 may correspond to one end of the channel part 141, for example, a left end and another end, for example, a right end, and may also correspond to one end and another end of the second gate electrode 160.

According to another embodiment of the present disclosure, by forming the first region 122al and the third region 122b1 to have the same first height h1 as the first portion 121, a phenomenon in which an electric field formed from the first portion 121 of the first gate electrode 120, the first region 122a1, and the third region 122b1 and applied to the active layer 140, and an electric field formed from the second gate electrode 160 and applied to the active layer 140 may be formed asymmetrically may be minimized, eliminated or reduced. And thus when the thin film transistor substrate according to another embodiment of the present disclosure is turned on, the HJS region may be removed, minimized or reduced, and a problem in which a lifespan of the thin film transistor substrate is shortened may be eliminated, minimized or reduced.

FIG. 7B is a cross-sectional view of a thin film transistor substrate according to another embodiment of the present disclosure. In this case, the cross-sectional view in FIG. 7B corresponds to the cross-section taken along the line VIII-VIII′ in FIG. 6. Meanwhile, since the embodiment in FIG. 7B is the same as the embodiment in FIG. 5B, different configurations will be mainly described below.

As shown in FIG. 7B, the first portion 121 of the first gate electrode 120 may overlap the channel part 141 of the active layer 140 and the second gate electrode 160 and may be formed to have a length shorter than the length of the channel part 141 and the second gate electrode 160 in the first direction X.

One end and another end of the first portion 121 may not correspond to one end and another end of the channel part 141, respectively, and may not correspond to one end and another end of the second gate electrode 160.

FIG. 8 is a plan view of a thin film transistor substrate according to another embodiment of the present disclosure. Meanwhile, the embodiment in FIG. 8 is the same as the embodiment in FIG. 1A except for a form in which the first gate electrode and the second gate electrode overlap each other, and thus different configurations will be mainly described below.

As shown in FIG. 8, the first gate electrode 120 and the second gate electrode 160 may overlap each other. In this case, the first gate electrode 120 and the second gate electrode 160 may be provided to partially deviate from each other. Specifically, a first central line L1 passing through the center of the first gate electrode 120 and a second central line L2 passing through the center of the second gate electrode 160 may not coincide on a plane view and may be formed to be spaced apart from each other in the first direction X.

Specifically, the first central line L1 may be spaced apart from the second central line L2 to be adjacent to the drain electrode 182 in the first direction X. Meanwhile, the present disclosure is not limited thereto, and the first central line L1 may be spaced apart from the second central line L2 to be adjacent to the source electrode 181 in the first direction X.

By forming a double gate structure in this way, a distance between one end, for example, the left end of the first portion 121 of the first gate electrode 120 and one end, for example, the left end of the second gate electrode 160 may be greater than a distance between another end, for example, the right end of the first portion 121 of the second gate electrode 160 and another end, for example, the right end of the second gate electrode 160.

Meanwhile, although not illustrated, the first gate electrode 120 may further move in the direction of the drain electrode 182 such that the first central line L1 may move in the direction of the drain electrode 182. In this case, another end of the first portion 121, for example, the right end, may coincide with another end of the second gate electrode 160.

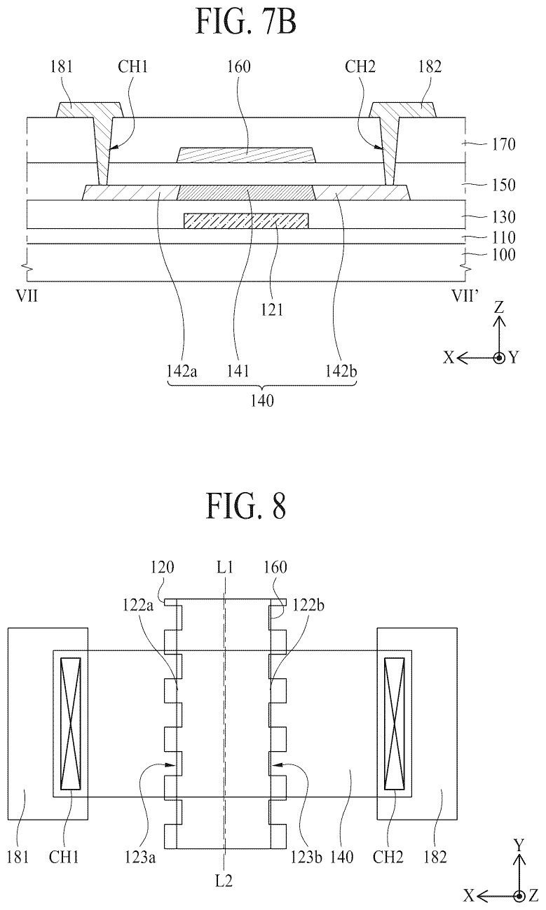

FIG. 9 is a plan view of a thin film transistor substrate according to another embodiment of the present disclosure. Meanwhile, the embodiment in FIG. 9 is the same as the embodiment in FIG. 1A except that a plurality of third portions and a plurality of second grooves are not provided, and thus different configurations will be mainly described below.

As shown in FIG. 9, the first gate electrode 120 may include a first portion 121 and a plurality of second portions 122 provided at one side of the first portion 121. In this case, one side of the first gate electrode 120, for example, a left side of the first gate electrode 120 and another side of the first gate electrode 120, for example, a right side of the first gate electrode 120 may be formed asymmetrically with respect to a straight line in the second direction Y passing through the center of the first gate electrode 120.

The plurality of second portions 122 may be provided on one side of the first gate electrode 120, and the plurality of grooves 123 may be provided between the plurality of second portions 122. The second gate electrode 160 may overlap a part of the first portion 121 and a part of each of the plurality of second portions 122a along the first direction X. The second gate electrode 160 may overlap a part of each second portion from a subset of second portions of the plurality of second portions 122a.

According to another embodiment of the present disclosure, as the plurality of grooves 123 are formed on one side of the first gate electrode 120, the area of a region where the first gate electrode 120 and the active layer 140 overlap each other, and do not overlap with the second gate electrode 160. By forming a double gate structure in this way, the HSJ region may be minimized or at least reduced in a region where the first gate electrode 120 and the active layer 140 overlap each other and do not overlap with the second gate electrode 160.

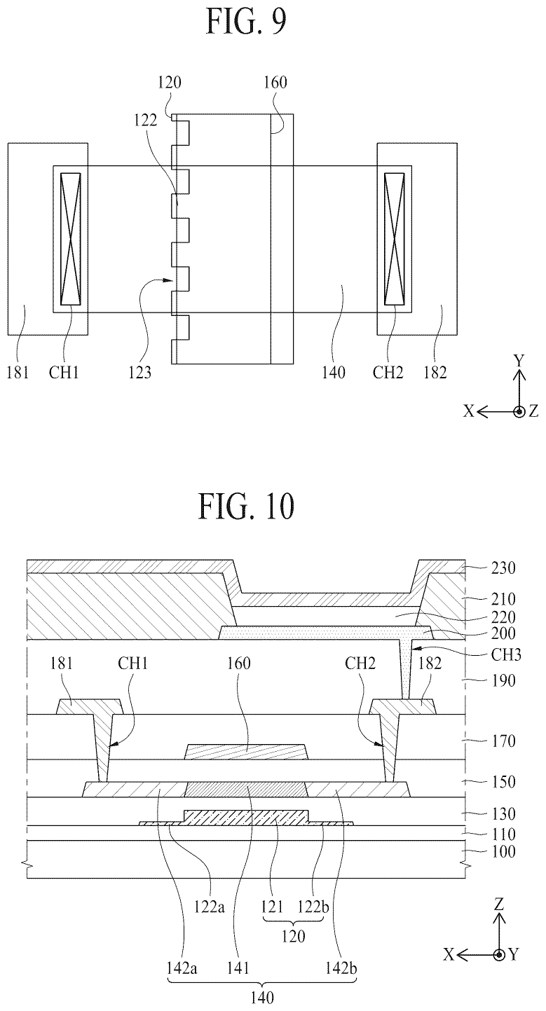

FIG. 10 is a cross-sectional view of a display device including a thin film transistor substrate according to an embodiment of the present disclosure.

As shown in FIG. 10, the display device according to an embodiment of the present disclosure may include a substrate 100, a buffer layer 110, a first gate electrode 120, a first gate insulating layer 130, an active layer 140, a second gate insulating layer 150, a second gate electrode 160, an interlayer insulating layer 170, a source electrode 181, a drain electrode 181, a planarization layer 190, a first electrode 200, a bank layer 210, a light emitting layer 220, a second electrode 230. In one or more embodiments, the first electrode 200, the bank layer 210, the light emitting layer 220, and the second electrode 230 form a light emitting element.

The substrate 100, the buffer layer 110, the first gate electrode 120, the first gate insulating layer 130, the active layer 140, the second gate insulating layer 150, the second gate electrode 160, the interlayer insulating layer 170, the source electrode 181 and the drain electrode 181 are the same as those described above, repeated descriptions thereof will be omitted.

A planarization layer 190 may be provided on the source electrode 181 and the drain electrode 182.

A third contact hole CH3 may be provided in the planarization layer 190 so that the source electrode 181 may be exposed by the third contact hole CH3. However, in some cases, the drain electrode 182 may be exposed by the third contact hole CH3.

The first electrode 200 may be formed on the planarization layer 190 and may be connected to the source electrode 181 or the drain electrode 182 through the contact hole. The first electrode 200 may function as an anode.

The bank layer 210 may be provided to cover an edge of the first electrode 200 to define a light emitting area. Accordingly, an upper surface area of the first electrode 200 exposed without being covered by the bank layer 210 becomes a light emitting area.

The light emitting layer 220 may be provided on the first electrode 200. The light emitting layer 220 may include red, green, and blue light emitting layers patterned for each pixel, or may be formed of a white light emitting layer connected from all pixels. When the light emitting layer 220 is formed of a white emission layer, the light emitting layer 220 may include, for example, a first stack including a blue emission layer, a second stack including a yellow green emission layer, and a charge generation layer provided between the first stack and the second stack, but is not limited thereto.

The second electrode 230 may be provided on the light emitting layer 220. The second electrode 230 may function as a cathode.

Although not shown, an encapsulation layer for preventing moisture or oxygen from penetrating may be additionally formed on the second electrode 230.

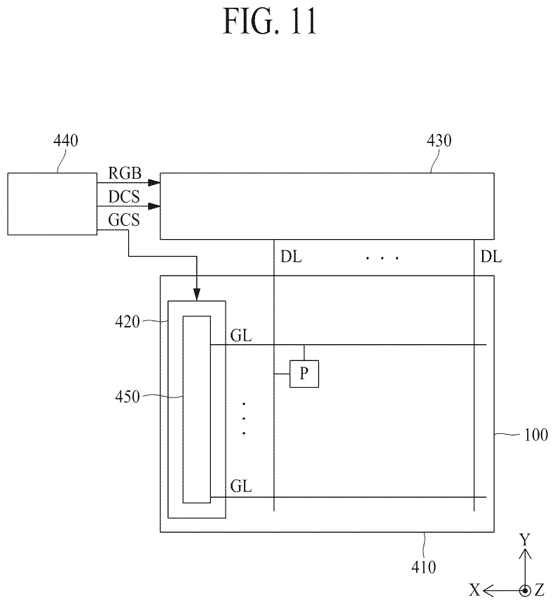

FIG. 11 is a schematic view of a display device according to an embodiment of the present disclosure.

As shown in FIG. 11, the display device according to an embodiment of the present disclosure may include a display panel 410, a gate driver 420, a data driver 430, and a controller 440.

The display panel 410 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100.

The controller 440 controls the gate driver 420 and the data driver 430. The controller 440 outputs a gate control signal GCS for controlling the gate driver 420 and a data control signal DCS for controlling the data driver 430 by using a signal supplied from an external system (not shown). Also, the controller 440 samples input video data input from the external system and rearranges the sampled input video data, and supplies the rearranged digital video data RGB to the data driver 430.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 430 supplies a data voltage to the data lines DL of the display panel 410. Specifically, the data driver 430 converts the video data RGB inputted from the controller 440 into an analog data voltage and supplies the data voltage to the data lines DL.

The gate driver 420 may be mounted on the display panel 410. As described above, a structure in which the gate driver 420 is directly mounted on the display panel 410 is referred to as a gate-in-panel (GIP) structure. Specifically, in the GIP structure, the gate driver 420 may be disposed on the substrate 100.

The gate driver 420 may include a shift register 350.

The shift register 350 sequentially supplies gate pulses to the gate lines GL during one frame by the use of start signal and gate clock transmitted from the controller 440. Herein, the one frame refers to a period in which one image is outputted through the display panel 410. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal GS.

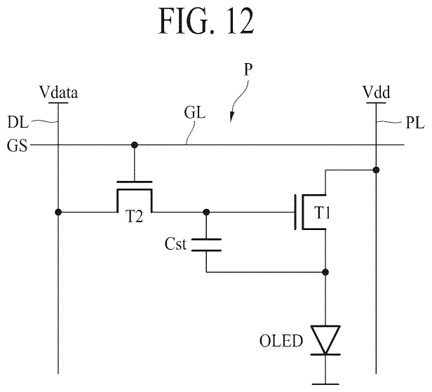

FIG. 12 is a circuit diagram of a pixel included in a display device according to an embodiment of the present disclosure.

As shown in FIG. 12, the display device according to an embodiment of present disclosure includes first to second thin film transistors T1 and T2 and capacitors Cst.

The first thin film transistor T1 is a driving thin film transistor, and the second thin film transistor T2 is a switching thin film transistor. At least one of the first thin film transistor T1 and the second thin film transistor T2 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

According to an embodiment of the present disclosure, the thin film transistor according to an embodiment of FIGS. 1A to 9 described above may be used as any one of the first thin film transistor T1 and the second thin film transistor T2.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

Accordingly, the present disclosure may have the following advantages.

According to an embodiment of the present disclosure, since the first gate electrode is provided with a plurality of grooves, an area of a portion that does not overlap with the second gate electrode is reduced while the first gate electrode and the active layer overlap each other, and thus a portion of the HSJ region may be removed. Accordingly, even if the thin film transistor substrate according to the embodiment of the present disclosure is turned on, the degree of fluctuation of the threshold voltage Vth is reduced, and furthermore, the problem of shortening the life of the thin film transistor substrate may be solved or at least mitigated.

According to an embodiment of the present disclosure, the first gate insulating layer provided on the first gate electrode has different thicknesses, so that the upper surface of the first gate insulating layer may be planarized, and the active layer is provided on the planarized first gate insulating layer, so that the distance between the first portion of the first gate electrode and the active layer may be shorter than the distance between a plurality of second portions of the first gate electrode and the active layer. In this case, by forming the distance between the plurality of second portions and the active layer to be increased, the intensity of the electric field applied to the active layer by the plurality of second portions on the active layer is reduced, and thus it may be controlled that the electric field applied from the first gate electrode and the second gate electrode is asymmetrically formed, and thus the HSJ region may be minimized or at least reduced. Accordingly, even if the thin film transistor substrate according to the embodiment of the present disclosure is turned on, the degree of fluctuation of the threshold voltage Vth is reduced, and furthermore, the problem of shortening the life of the thin film transistor substrate may be solved or at least mitigated.

According to an embodiment of the present disclosure, at least a portion of a plurality of grooves provided in the first gate electrode overlaps the second gate electrode, and thus an electric field applied from the first gate electrode and the second gate electrode to the active layer may be asymmetrically formed even if the central line of the first gate electrode and the central line of the second gate electrode partially deviate due to an actual process error.

According to an embodiment of the present disclosure, a plurality of second portions of the first gate electrode include the first region and the second region having different thicknesses, and the first portion and the first region of the plurality of second portions are provided to have the same thickness, so that the electric field applied to the active layer from the first gate electrode and the second gate electrode may be asymmetrically formed. Therefore, even if the thin film transistor substrate according to the embodiment of the present disclosure is turned on, the degree of fluctuation of the threshold voltage Vth is reduced, and furthermore, the problem of shortening the life of the thin film transistor substrate may be solved or at least mitigated.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate, comprising:
a substrate;
a first gate electrode on the substrate, the first gate electrode including a first portion and a second portion;
an active layer on the first gate electrode;
a second gate electrode on the active layer, the second gate electrode overlapping at least the first portion of the first gate electrode;
a source electrode connected to a first side of the active layer; and
a drain electrode connected to a second side of the active layer,
wherein the second portion protrudes from an end of the first portion in a first direction towards one of the source electrode or the drain electrode, and a thickness of the second portion is smaller than a thickness of the first portion.

2. The thin film transistor substrate according to claim 1, wherein an end of the second gate electrode overlaps a region extending from a boundary between the first portion and the second portion to an end of the second portion.

3. The thin film transistor substrate according to claim 1, wherein a distance between the first portion and the active layer is smaller than a distance between the second portion and the active layer.

4. The thin film transistor substrate according to claim 3, further comprising:
a first gate insulating layer between the first gate electrode and the active layer,
wherein a first thickness of a first portion of the first gate insulating layer overlapping the first portion is smaller than a second thickness of a second portion of the first gate insulating layer overlapping the second portion.

5. The thin film transistor substrate according to claim 1,
wherein the first gate electrode further includes a third portion protruding from another end of the first portion in a second direction towards another of the source electrode or the drain electrode, the second direction opposite to the first direction, and
wherein a thickness of the third portion is smaller than the thickness of the first portion.

6. The thin film transistor substrate according to claim 1, wherein the active layer includes:
a channel part;
a first connection part on a first side of the channel part; and
a second connection part on a second side of the channel part that is opposite the first side of the channel part,
wherein the channel part overlaps the first portion of the first gate electrode, and an end of the channel part overlaps a region extending from a boundary between the first portion and the second portion to an end of the second portion.

7. The thin film transistor substrate according to claim 1, wherein the second portion includes a first region in contact with the end of the first portion and a second region extending from the first region, and a thickness of the first region is smaller than a thickness of the second region.

8. A thin film transistor substrate, comprising:
a substrate;
a first gate electrode on the substrate, the first gate electrode including a first portion and a plurality of second portions, the plurality of second portions spaced apart from each other with a plurality of first grooves interposed between the plurality of second portions;
an active layer on the first gate electrode;
a second gate electrode on the active layer, the second gate electrode overlapping at least a portion of the first gate electrode;
a source electrode connected to a first side of the active layer; and
a drain electrode connected to a second side of the active layer,
wherein the plurality of second portions protrude from an end of the first portion in a first direction towards the source electrode or the drain electrode, and
wherein an end of the second gate electrode overlaps a region from a first end of the first portion to an end of a second portion of the plurality of second portions that is connected to a second end of the first portion.

9. The thin film transistor substrate according to claim 8, wherein the end of the second gate electrode overlaps the plurality of first grooves.

10. The thin film transistor substrate according to claim 8, wherein the first gate electrode further includes a plurality of third portions protruding from the second end of the first portion in a second direction towards another of the source electrode or the drain electrode, the second direction opposite to the first direction, the plurality of third portions spaced apart from each other with a plurality of second grooves interposed between the plurality of third portions.

11. The thin film transistor substrate according to claim 10, wherein another end of the second gate electrode overlaps a region extending from the second end of the first portion to an end of a third portion of the plurality of third portions that is connected to the first end of the first portion.

12. The thin film transistor substrate according to claim 10, wherein a first central line passing through a center of the first gate electrode and a second central line passing through a center of the second gate electrode are misaligned relative to each other on a plane view of the thin film transistor substrate.

13. The thin film transistor substrate according to claim 8, wherein at least a subset of the plurality of second portions and at least a subset of the plurality of first grooves overlap the active layer.

14. The thin film transistor substrate according to claim 8,
wherein the active layer includes a channel part, a first connection part on a first side of the channel part, and a second connection part on a second side of the channel part, and
wherein the first side of the channel part overlaps a region extending from a boundary between the first portion and the second portion to the end of the second portion.

15. A display device comprising:
a light emitting element; and
the thin film transistor substrate according to claim 1 that is connected to the light emitting element.

16. A thin film transistor substrate, comprising:
a first gate electrode extending in a first direction, the first gate electrode including a first portion and a plurality of second portions that protrude from a first end of the first portion along a second direction that is different than the first direction, the plurality of second portions spaced apart from each other;
an active layer on the first gate electrode and extending in the second direction, the active layer partially overlapping the first portion and a subset of the plurality of second portions along the first direction;
a source electrode connected to a first side of the active layer;
a drain electrode connected to a second side of the active layer, the second side of the active layer opposite to the first side of the active layer along the second direction; and
a second gate electrode on the active layer and extending in the first direction, the second gate electrode partially overlapping the first gate electrode along the second direction without overlapping ends of the plurality of second portions.

17. The thin film transistor substrate according to claim 16, wherein the second gate electrode overlaps an entirety of the first portion of the first gate electrode along the first direction and the second direction.

18. The thin film transistor substrate according to claim 16, wherein the second gate electrode overlaps a part of the first portion of the first gate electrode and a part of each of the plurality of second portions of the first gate electrode along the second direction.

19. The thin film transistor substrate according to claim 16, wherein each two adjacent second portions of the plurality of second portions are spaced apart by a respective groove of a plurality of grooves.

20. The thin film transistor substrate according to claim 16, wherein the active layer includes a channel part, a first connection part extending in the second direction towards the source electrode and connected to the source electrode, and a second connection part extending in the second direction towards the drain electrode and connected to the drain electrode.

21. The thin film transistor substrate according to claim 20, wherein each of the first connection part and the second connection part has a stepped form.

22. The thin film transistor substrate according to claim 20,
wherein the channel part overlaps the first portion of the first gate electrode, and
wherein one of the first connection part and the second connection part overlaps a subset of the plurality of second portions of the first gate electrode.

23. The thin film transistor substrate according to claim 16, wherein the first gate electrode further includes a plurality of third portions spaced apart from each other, the plurality of third portions protruding from a second end of the first portion along the second direction, the second end of the first portion opposite to the first end of the first portion along the second direction.

24. The thin film transistor substrate according to claim 16, wherein a thickness of the first portion of the first gate electrode is greater than a thickness of each of the plurality of second portions of the first gate electrode.

25. The thin film transistor substrate according to claim 16, wherein a distance from the active layer to the first portion of the first gate electrode along a third direction is same as a distance from the active layer to a second portion of the plurality of second portions of the first gate electrode along the third direction, the third direction different from the first direction and the second direction.

26. The thin film transistor substrate according to claim 16, wherein a distance from the active layer to the first portion of the first gate electrode along a third direction is smaller than a distance from the active layer to a second portion of the plurality of second portions of the first gate electrode along the third direction, the third direction different from the first direction and the second direction.

27. The thin film transistor substrate according to claim 16, wherein the second gate electrode is non-overlapping with the plurality of second portions of the first gate electrode.

28. The thin film transistor substrate according to claim 16, wherein the second gate electrode overlaps a part of each second portion from a subset of second portions of the plurality of second portions of the first gate electrode.
